(19) United States
(12) Patent Application Publication
(10) Pub. No.: US 2024/0333263 A1
(43) Pub. Date: Oct. 3, 2024

(54) METHODS AND APPARATUS TO IMPROVE FLIP-FLOP TOGGLE EFFICIENCY

(71) Applicant: Intel Corporation, Santa Clara, CA (US)

(72) Inventors: Chinmay Pradeep Joshi, Portland, OR (US); Dinesh Somasekhar, Portland (UA); David Edward Bradley, Fort Collins, CO (US); Radhika Kudva, Beaverton, OR (US)

(21) Appl. No.: 18/191,562

(22) Filed: Mar. 28, 2023

(51) Int. Cl. H03K 3/012; H03K 3/037

(52) U.S. Cl. CPC H03K 3/012; H03K 3/0372

(57) ABSTRACT

Methods and apparatus are disclosed to improve flip-flop toggle efficiency. An example circuit includes an upper flip-flop latch circuit including a first clock input terminal, a first output terminal, and a first data input terminal, a first gating circuit including a first gating transistor, the first gating transistor including a first power input terminal, a first gating output terminal and a gating signal input terminal, the gating signal input terminal coupled to the first input terminal of the first flip-flop latch circuit, a first clock transistor including a clock power input terminal coupled to the first gating output terminal of the first gating transistor, a clock power output terminal, and a clock signal input terminal coupled to the first clock input terminal of the upper flip-flop latch circuit, and a first latch output transistor including a latch power input terminal, a latch power output terminal coupled to the clock power output terminal of the first clock transistor, and a latch input terminal coupled to an output of a second latch output transistor of the upper flip-flop latch circuit.

### FIELD OF THE DISCLOSURE

This disclosure relates generally to circuits and, more particularly, to methods and apparatus to improve flip-flop toggle efficiency.

### BACKGROUND

In recent years, energy conservation efforts have increased in jurisdictions throughout the world. Circuits marketed, sold and/or otherwise operated in some jurisdictions are subject to energy consumption criteria that must be satisfied prior to operational authorization in such jurisdictions.

### BRIEF DESCRIPTION OF THE DRAWINGS

FIG. 1 is an example implementation of a data multiplexer scan flip-flop circuit.

FIG. 2 is an example implementation of a single-phase, clocked, edge-triggered flip-flop using complementary metal-oxide semiconductor (CMOS) logic gates.

FIGS. 3 and 4 are example implementations of self-gating circuits corresponding to zero-catcher set-reset (SR) latches to improve flip-flop toggle efficiency.

FIG. 5 is an example implementation of a self-gating flip-flop that includes the example self-gating circuits of FIGS. 3 and 4.

FIG. 6 is an example implementation of the self-gating flip-flop of FIG. 5 showing example transistor structure.

FIG. 7A is an example timing diagram illustrating flip-flop node activity during clock cycles.

FIG. 7B is a flowchart representative of example machine readable instructions and/or example operations that may be executed, instantiated, and/or performed by example programmable circuitry to implement the self-gating flip-flop of FIGS. 5 and 6.

FIG. 8 is a block diagram of an example processing platform including programmable circuitry structured to include, execute, instantiate, and/or perform the example operations of self-gating flip-flops disclosed herein.

In general, the same reference numbers will be used throughout the drawing(s) and accompanying written description to refer to the same or like parts. The figures are not necessarily to scale.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. In some examples, the language “above” is not with reference to Earth, but instead is with reference to another transistor device(s). Thus, as used herein and unless otherwise stated or implied from the context, a first component within a semiconductor die (e.g., a transistor or other semiconductor device) is “above” a second component (e.g., a transistor) within the semiconductor die when the first component is farther away from a substrate (e.g., a semiconductor wafer) or the second component during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

The term “couple”, “coupled”, “couples”, and variants thereof, as used herein, may cover connections, communications, or signal paths that enable a functional relationship consistent with this description. For example, if device A generates a signal to control device B to perform an action, in a first example device A is coupled to device B, or in a second example device A is coupled to device B through intervening component C if intervening component C does not substantially alter the functional relationship between device A and device B such that device B is controlled by device A via the control signal generated by device A. Moreover, the terms “couple”, “coupled”, “couples”, or variants thereof, includes an indirect or direct electrical or mechanical connection.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

Although not all separately labeled in the figures described below, components or elements of systems and circuits illustrated therein have one or more conductors or terminus that allow signals into and/or out of the components or elements. The conductors or terminus (or parts thereof) may be referred to herein as pins, pads, terminals (including input terminals, output terminals, reference terminals, and ground terminals, for instance), inputs, outputs, nodes, vias and interconnects.

As used herein, a “terminal” of a component, device, system, circuit, integrated circuit, or other electronic or semiconductor component, generally refers to a conductor such as a wire, trace, pin, pad, via or other connector or interconnect that enables the component, device, system, etc., to electrically and/or mechanically connect to another component, device, system, etc. A terminal may be used, for instance, to receive or provide analog or digital electrical signals (or simply signals) or to electrically connect to a common or ground reference. Accordingly, an input terminal or input is used to receive a signal from another component, device, system, etc. An output terminal or output is used to provide a signal to another component, device, system, etc. Other terminals may be used to connect to a common, ground, or voltage reference, e.g., a reference terminal or ground terminal. A terminal of an IC or a PCB may also be referred to as a pin (a longitudinal conductor) or a pad (a planar conductor). A node refers to a point of connection or interconnection of two or more terminals. An example number of terminals and nodes may be shown. However, depending on a particular circuit or system topology, there may be more or fewer terminals and nodes. However, in some instances, “terminal”, “node”, “interconnect”, “pad”, and “pin” may be used interchangeably.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

In the description and in the claims, the terms “including” and “having” and variants thereof are intended to be inclusive in a manner similar to the term “comprising” unless otherwise noted. Unless otherwise stated, “about,” “approximately,” or “substantially” preceding a value means +/−10 percent of the stated value. In another example, “about,” “approximately,” or “substantially” preceding a value means +/−5 percent of the stated value. IN another example, “about,” “approximately,” or “substantially” preceding a value means +/−1 percent of the stated value.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

### DETAILED DESCRIPTION

Flip-flops are fundamental sequential logic elements in digital logic design. In some examples, D-type flip flops are employed in system-on-a-chip (SoC) circuits to take advantage of performance preferences and/or characteristics. However D-type flip-flops exhibit total dynamic power (TDP) consumption characteristics when implemented in various environments, such as data center processor circuitry. TDP includes, but is not limited to clock power consumption characteristics, internal switching power characteristics and leakage power characteristics.

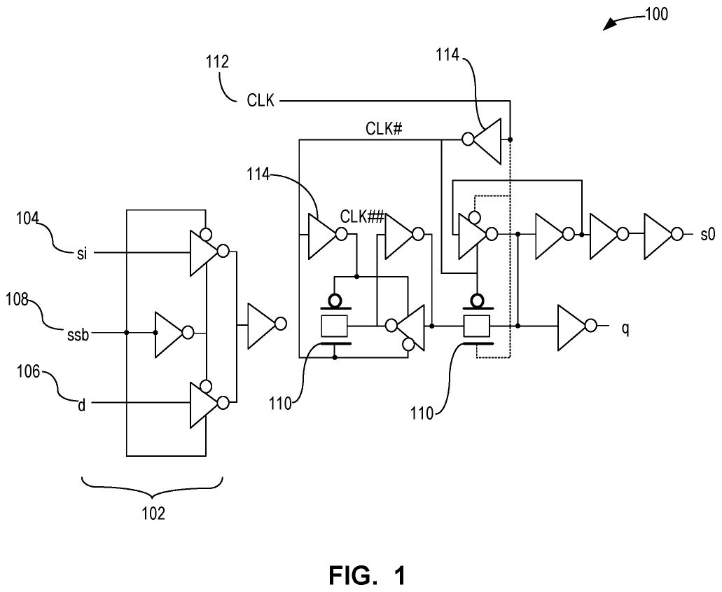

Flip-flops in a primary/secondary configuration typically exhibit internal switching behaviors that cause secondary output only during particular clock cycle conditions. FIG. 1 illustrates an existing data multiplexer (MUX-D) scan flip-flop 100. In the illustrated example of FIG. 1, the MUX-D scan flip-flop 100 includes MUX 102 having a scan input (si) 104, a data input (d) 106, and a scan control (ssb) input 108. Additionally, the example MUX-D scan flip-flop 100 includes one or more t-gates 110, a clock input 112, and clock inverters 114. Existing MUX-D scan flip-flops typically employ the t-gates 110 and the clock inverters 114 to generate both polarities of a clock phase. Such designs include one or more nodes toggling at the clock rate regardless of whether the flip-flop input 106 is changing/switching/toggling. In particular, such internal switching occurs when input signals are non-transient (e.g., unchanged) and/or otherwise not changing (e.g., a data input terminal). When internal switching occurs, the flip-flop circuit consumes power. Examples disclosed herein include circuit configurations that reduce internal switching behaviors (e.g., prohibit a state change) unless input signals (e.g., data input signals) change, thereby reducing power consumption of flip-flop operation(s).

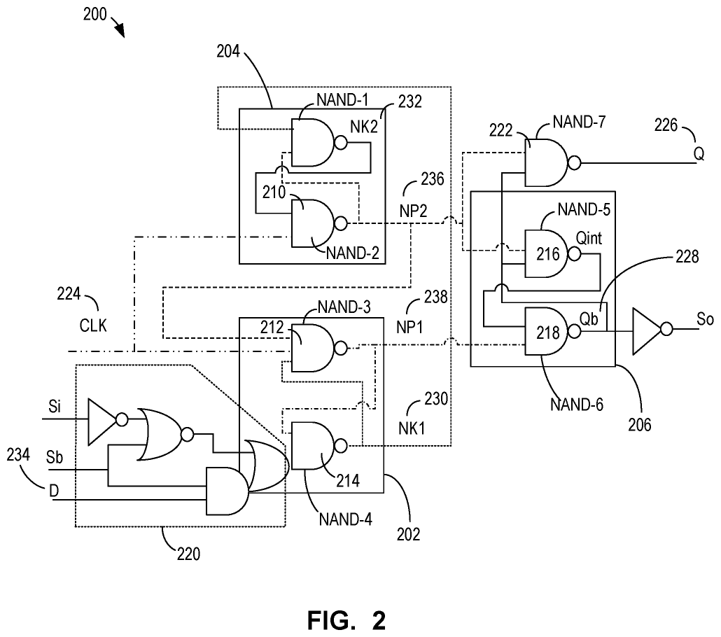

FIG. 2 illustrates a schematic of an example single phase clocked edge-triggered flip-flop circuit 200 using complementary metal-oxide semiconductor (CMOS) logic gates. In the illustrated example of FIG. 2, the flip-flop circuit 200 includes a first zero-catcher set-reset (SR) latch 202 (sometimes referred to herein as a set-reset latch, a flip-flop latch circuit, a lower zero-catcher latch circuit, or more generally an SR latch), an upper zero-catcher SR latch 204 (sometimes referred to herein as a zero-catcher latch circuit, or an upper zero-catcher latch circuit) and a third zero-catcher SR latch 206 (sometimes referred to herein as a zero-catcher latch circuit). The example flip-flop 200 also includes a first NAND gate 208 (NAND-1), a second NAND gate 210 (NAND-2), a third NAND gate 212 (NAND-3), a fourth NAND gate 214 (NAND-4), a fifth NAND gate 216 (NAND-5), a sixth NAND gate 218, and a seventh NAND gate 222 (NAND-7). While the illustrated example of FIG. 2 includes different gate types and corresponding symbols, underlying transistor structure arrangement may vary, and is described in further detail below. In the illustrated example of FIG. 2, the upper zero-catcher SR latch 204 facilitates cross-coupled gates between node NK2 232 and node NP2 236, and the first zero-catcher SR latch 202 facilitates cross coupled gates between node NK1 230 and node NP1 238. As used herein, a “node” represents a portion of a logic gate and/or a transistor terminal. In some examples disclosed herein, the language “node” and “terminal” may be used interchangeably. The example flip-flop 200 of FIG. 2 also includes an And-Or-And-Invert (AOAI) gate 220, sometimes referred to herein as a complex logic gate, a complex logic circuit, or an AOAI circuit. The example AOAI gate 220 forms an embedded mux-D for Si and D inputs and absorbs feedback from node NP1 238.

As described above, traditional flip-flop implementations exhibit internal switching of particular nodes during clock cycle iterations, even when there are no changes to an input (e.g., D 234). For instance, when a clock node 224 (e.g., a clock input terminal (clock signal) of the example upper flip-flop latch circuit 204) is at a low phase of logic zero, both the first zero-catcher SR latch 202 and the upper zero-catcher SR latch 204 are locked out with node NP2 236 and NP1 238 being driven to logic one (high). In this particular state, output node (Q) 226 and inverted output node (Qb) 228 preserve any previous values they may have had (and are complementary). Additionally, in this state node NK1 230 and node NK2 232 are set to an inversion of input and the same logic value as input, respectively. The fact that input node (D) 234 is logically reflected on node NK1 230 and node NK2 232, with node NP1 238 and node NP2 236 set high means that the SR latches are primed to capture the value of the input D 234.

When the clock node 224 receives a high edge signal, NAND-3 212 and NAND-2 210 are activated to capture the value of node NK2 232 and node NK1 230, which would flow through to the output Q 226 (and Qb). At this phase, node NP2 236 and node NP1 238 exhibit a complementary behavior (because node NK1 230 and node NK2 232 were previously complementary and the activation of the aforementioned NAND gates propagates these complementary values to nodes NP1 238 and NP2 236).

When the clock node 224 remains at a high value, note that any changes to the input D 234 will not propagate to the output Q 226. Consider an example phase where the input D 234 is initially low, in which case node NK1 230 would initially be high (and complementary node NK2 232 would be low). During the high transition of the clock node 224, node NP1 238 goes low and node NP2 236 remains high. Because node NP1 238 is low, the example AOAI gate 220 is disabled and node NK1 230 is no longer responsive to the input D 234.

However, again when the clock node 224 transitions to a high value, consider an example phase where the input D 234 is initially high at the point when the clock node 224 value was initially low. In this phase, node NK1 230 is low and node NK2 232 is high. With the clock node 224 transitioning to high, node NP1 238 remains high, but node NP2 236 is being forced low. Notice that the feedback of node NP2 236 to NAND-3 212 would keep node NP1 238 to remain high regardless of any other inputs to NAND-3 212. In particular, this extra half-cross couple allows node NP1 238 and node NP2 236 to remain locked even when the input D 234 transitions to a low value. In particular, node NK1 230 transitions to a high value in this scenario, but because node NP2 236 is low, changes to the input D 234 do not propagate to node NK2 232. As such, the example flip-flop 200 of FIG. 2 implements a true flip-flop functionality and is responsive only to the rising edge of the clock node 224.

Continuing with the above example, even while the input D 234 remains high, during the next/subsequent positive edge of the clock node 224, node NP2 236 transitions to a logic low and the output Q 226 is high. Despite no changes in the input D 234, for every logic-zero phase of the clock node 224, node NP2 236 transitions to a logic high and will discharge to a logic low with every positive edge of that clock node 224. In other words, despite no changes to the input D 234 (e.g., a non-transient input), internal transistor switching occurs, thereby consuming power in the example flip-flop 200. Examples disclosed herein avoid unnecessary internal transistor switching so that during a low phase of the clock node 224, the node NP2 236 will charge to a high value only in the event the input D 234 is changing to a low value. As such, examples disclosed herein enable setting of node NK1 230 and node NK2 232 as a reflection of input D 234 to allow the first SR latch 202 and the upper SR latch 204 primed to capture such input D 234. Similarly, with respect to node NP1 238, examples disclosed herein disable charging of node NP1 238 to a high value until the input D 234 changes to a logic high value (or an inverted input changes to a logic low value).

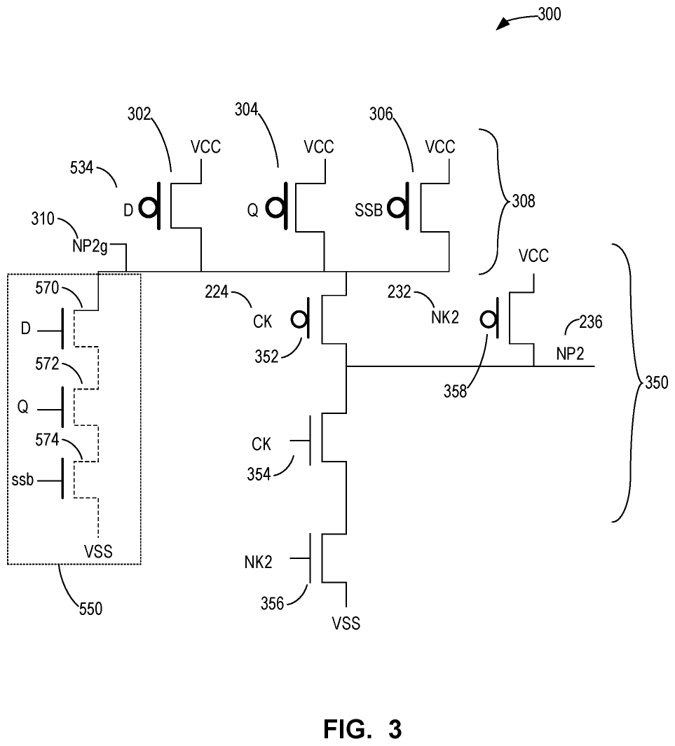

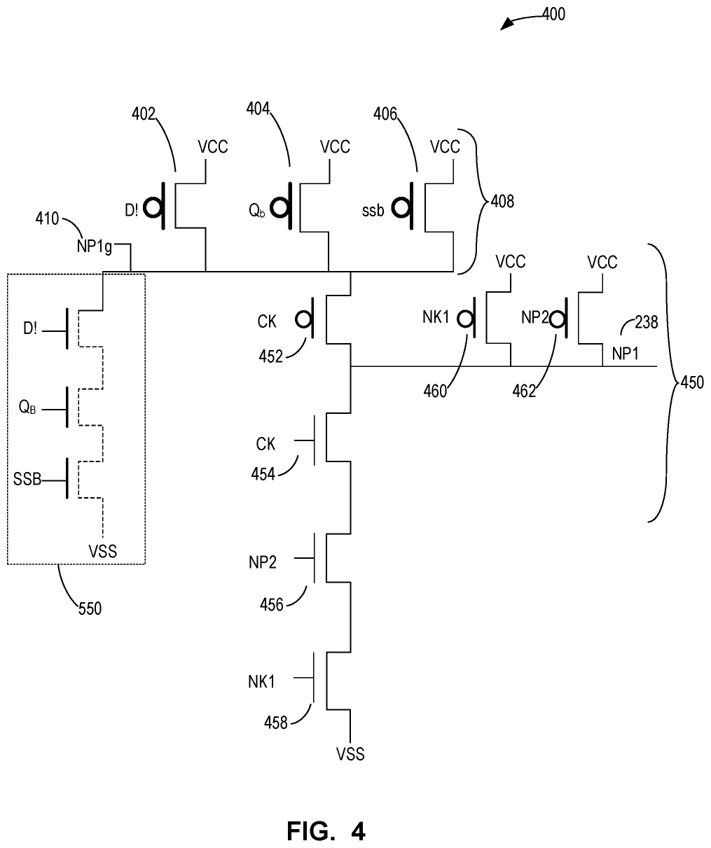

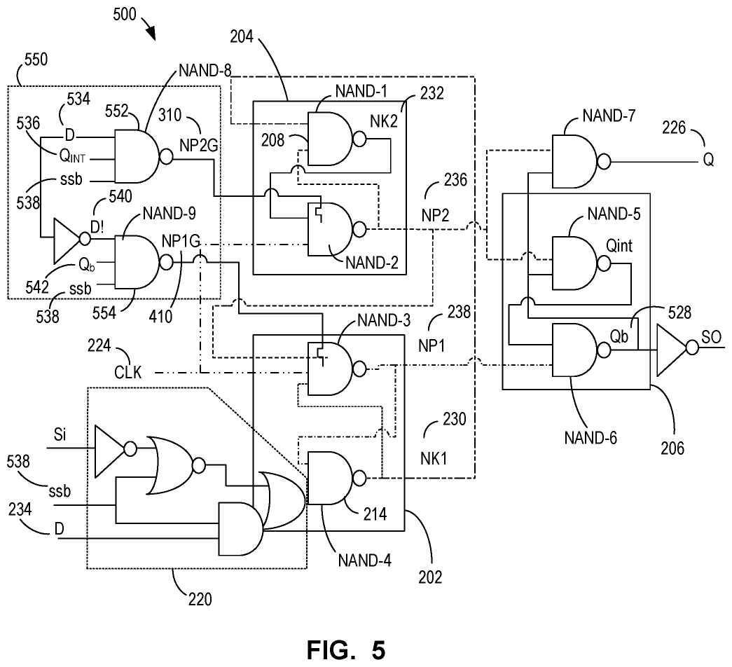

FIG. 3 and FIG. 4 illustrate example circuit modifications to the illustrated example of FIG. 2 to enable self-gating. As used herein, self-gating refers to reduction or elimination of internal node switching unless and until a change to an input occurs (e.g., a transient input condition). In particular, the illustrated example of FIG. 3 includes a self-gating circuit 300 (sometimes referred to herein as self-gating modifiers 300) corresponding to the example upper zero-catcher SR latch 204 (e.g., the upper flip-flop latch circuit 204). Additionally, the illustrated example of FIG. 4 includes a self-gating circuit 400 corresponding to the example first zero-catcher SR latch 202 (e.g., the lower flip-flop latch circuit 202). For purposes of illustration, and not limitation, the illustrated example of FIG. 3 will be discussed below to convey self-gating in a manner that preserves flip-flop power consumption and, in some cases, enables a transistor count to facilitate die space conservation. Additionally, to illustrate the example self-gating circuit 300 of FIG. 3 and the example self-gating circuit 400 of FIG. 4, the aforementioned self-gating circuits will be described in connection with an example self-gating flip-flop of FIG. 5. The example self-gating flip-flop of FIG. 5 includes similar nodes, transistors and connections as shown in the illustrated example of FIG. 2, which are labeled with a similar “200-series” nomenclature. Modifications from FIG. 2 are shown in the illustrated example flip-flop of FIG. 5 using a “500-series” nomenclature.

In the illustrated example of FIG. 3, the self-gating circuit 300 includes a first data input transistor 302 (sometimes referred to as a first gating transistor 302) to accept values from an example input node (D) 534 of FIG. 5, which has the same logical values as the example input node (D) 234 of FIG. 2. The example first gating transistor 302 includes a first power input terminal (Vcc), a gating signal input terminal (see input node (D) 534), and a first gating output terminal (sometimes referred to as a self gating terminal). The example self-gating circuit 300 also includes a second output (Q) transistor 304 and an example third scan control (ssb) transistor 306. In the illustrated example of FIG. 3, the combination of the first transistor 302, the second transistor 304 and the third scan control transistor 306 forms a common node 308, which is sometimes referred to as a first gating circuit 308, a common terminal, or a common terminal circuit. In some examples, the transistors of the common node 308 are P-type metal-oxide semiconductor (PMOS) transistors to cut-off power to the example self-gating circuit 300. The example common node 308 forms node NP2g 310, sometimes referred to herein as a first gating output terminal 310. The illustrated example of FIG. 3 also includes a tail circuit 550, sometimes referred to as tail nodes or tail terminals and discussed in further detail below in connection with FIG. 5. The example tail circuit 550 includes a data (D) input transistor 570 (sometimes referred to herein as a tail input transistor 570), an output (Q) transistor 572 (sometimes referred to herein as a tail output transistor 572), and a scan control (ssb) transistor 574 (sometimes referred to herein as a scan enable transistor 574).

The example combination of transistors of the tail circuit 550 is sometimes referred to herein as a series stack of input transistors, and is shown in the illustrated example of FIG. 3 as being implemented by NMOS transistors. Similarly, the example series stack 550 of FIG. 4 is shown as being implemented by NMOS transistors. However, such implementations are shown for example purposes and not limitations of the type(s) of transistors capable of facilitating example self-gating techniques disclosed herein. For example, a complementary arrangement of transistors may be implemented from what is shown in FIGS. 3 and/or 4. In particular, alternate implementations that employ opposite transistor types (e.g., PMOS changed to NMOS, or NMOS changed to PMOS) may occur. For instance, in the event Vcc and Vss of FIG. 3 were switched, all the NMOS transistors were changed to PMOS transistors, and all the PMOS transistors were changed to NMOS transistors, then self-gating techniques and structure disclosed herein will operate. Similar complementary modifications are possible in view of the illustrated example of FIG. 4.

The example series stack of input transistors is coupled to a parallel stack of input transistors of the common node 308, as shown in FIG. 3. The example self-gating circuit 300 of FIG. 3 also includes a lower stack 350, which includes a first clock transistor 352, a second clock transistor 354, a first NK2 node transistor 356 (sometimes referred to herein as a latch output transistor), and a second NK2 node transistor 358. The example first clock transistor 352 includes a clock power input terminal coupled to the first gating output terminal 310 of the first gating transistor 302. The example first clock transistor 352 also includes a clock power output terminal coupled to node NP2 236 of the upper flip-flop latch circuit 204. The example second NK2 node transistor 358 includes a terminal corresponding to the node NK2 232, sometimes referred to herein as a latch output terminal or a latch power output terminal, which is coupled to an output of the second latch output transistor 356 of the upper flip-flop latch circuit 204. The example second NK2 node transistor 358 also includes a terminal corresponding to Vcc, sometimes referred to herein as a latch power input terminal.

The example self-gating circuit 400 of FIG. 4 includes a portion of the example tail circuit 550, and a common node 408 that includes a first data input transistor 402 (sometimes referred to herein as a first gating transistor 402), a second output transistor 404, and a third scan control transistor 406. The example self-gating circuit 400 of FIG. 4 also includes a lower stack 450, which includes a first clock transistor 452, a second clock transistor 454, a first NP2 node transistor 456, a first NK1 transistor 458, a second NK1 transistor 460, and a second NP2 node transistor 462.

Turning back to the illustrated example of FIG. 3, two possible states may occur for the example common node 308. A first state is when one of the first gating transistor 302, the second output transistor 304, or the third scan control (enable) transistor 306 is on (conducting), meaning that the input value to the transistor gate nodes is low. As such, node NP2g 310 will be at Vcc. A second state is when all of the common node 308 transistors are off (not conducting), meaning that the input value to the transistor gate nodes is high. As such, node NP2g 310 is cut-off and/or otherwise isolated from Vcc. In operation, when the clock node 224 is low, then the value for node NP2 236 is indeterminate. Examples disclosed herein prevent such an indeterminate state by guaranteeing that the input node 234 and the output node 226 are not the same value with respect to node NK2 232. In particular, the example self-gating circuit 300 establishes a relationship between the input node D 534 and the output node Q are not the same with respect to NK2 232.

Turning to the illustrated example of FIG. 5, a self-gating flip flop circuit 500 includes several of the same aspects, transistors and nodes as described above in connection with the example flip-flop circuit 200 of FIG. 2. However, additional and/or alternate features of the example self-gating flip-flop circuit 500 of FIG. 5 are referred to with a 500-series nomenclature. Additionally, similar nodes and/or structure between the example self-gating circuit 300 of FIG. 3 and the example self-gating flip-flop 500 of FIG. 5 share similar nomenclature (e.g., similar numeric reference numbers). As described above, the example self-gating flip-flop 500 includes a tail circuit 550 as inputs to the example first zero-catcher SR latch 202 (e.g., the lower flip-flop latch circuit 202) and the example second zero-catcher SR latch 204 (e.g., the upper flip-flop latch circuit 204) to prevent and/or otherwise suppress floating conditions of internal nodes of the flip-flop circuit 500. The example tail circuit 550 includes an eighth NAND gate 552 (NAND-8), a ninth NAND gate 554 (NAND-9), a data node (D) 534 (which follows the value of the data node (D) 234), a Qint node 536, a scan control (ssb) node 538, an inverted data node (D!) 540, and an inverted output node (Qb) 542.

In operation, the data input D 234 and scan control (ssb) 538 of FIG. 5 are tied together so that when the scan control goes to zero, the data input D 234 is cut off. However, with the scan control (ssb) 538 at zero within the tail circuit 550, the corresponding eighth NAND gate 552 (NAND-8) and the ninth NAND gate 554 (NAND-9) turn on to cause node NP2g 310 and node NP1g 410 to turn on. Accordingly, the intermediate nodes are at Vcc. Turning briefly to the illustrated example of FIG. 3, when the example common node 308 includes all high inputs, node NP2g 310 is forced to zero. In other words, this is no longer floating and node NP1 238 and node NP2 236 are preserved with their previous values without flipping and/or otherwise transitioning during clock cycles. Stated differently, node NP2 236 will charge on the low phase of a clock cycle only when one of the transistors of the common node 308 are closed.

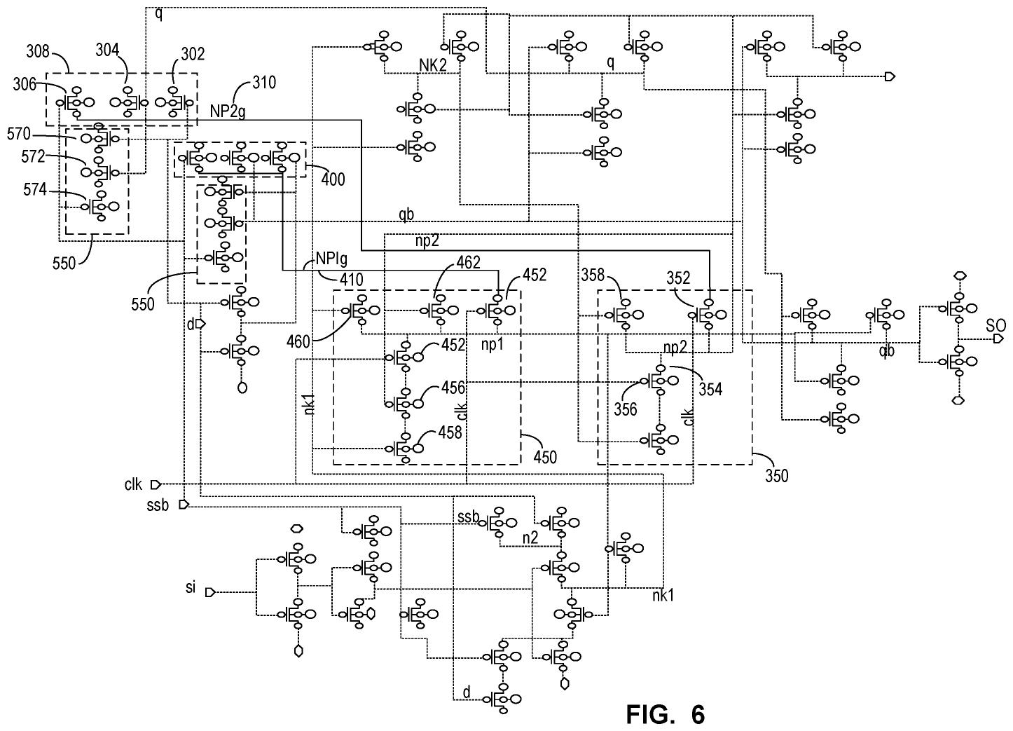

FIG. 6 is a transistor schematic of an example self-gating flip-flop circuit 600 that includes the self-gating circuitry 300 of FIG. 3, the self-gating circuitry 400 of FIG. 4, and the tail circuit 550 of FIG. 5 to enable flip-flop operation without internal node switching. In the illustrated example of FIG. 6, the flip-flop 600 circuit includes the same nomenclature, nodes and transistors as described above, but represented as an example transistor-level flip-flop circuit suitable for production and/or manufacturing. The example flip-flop circuit 600 of FIG. 6 includes example transistor structure consistent with the example self-gating flip flop 500 of FIG. 5. In particular, the illustrated example of FIG. 6 conveys an alternate view of blocking nodes NP1 and NP2 with nodes NP1g 410 and NP2g 310. Stated differently, when inputs to the example common node 308 and inputs to the example tail circuit 550 (corresponding to NP2g 310) are all at a value of one, then NP2g 310 is forced to zero that, as such, prevents floating of the intermediate node NP2 236. As such, when NP2g 310 is forced to zero, the example circuit of FIG. 6 preserves values of node NP1 and NP2 236 to prevent flipping.

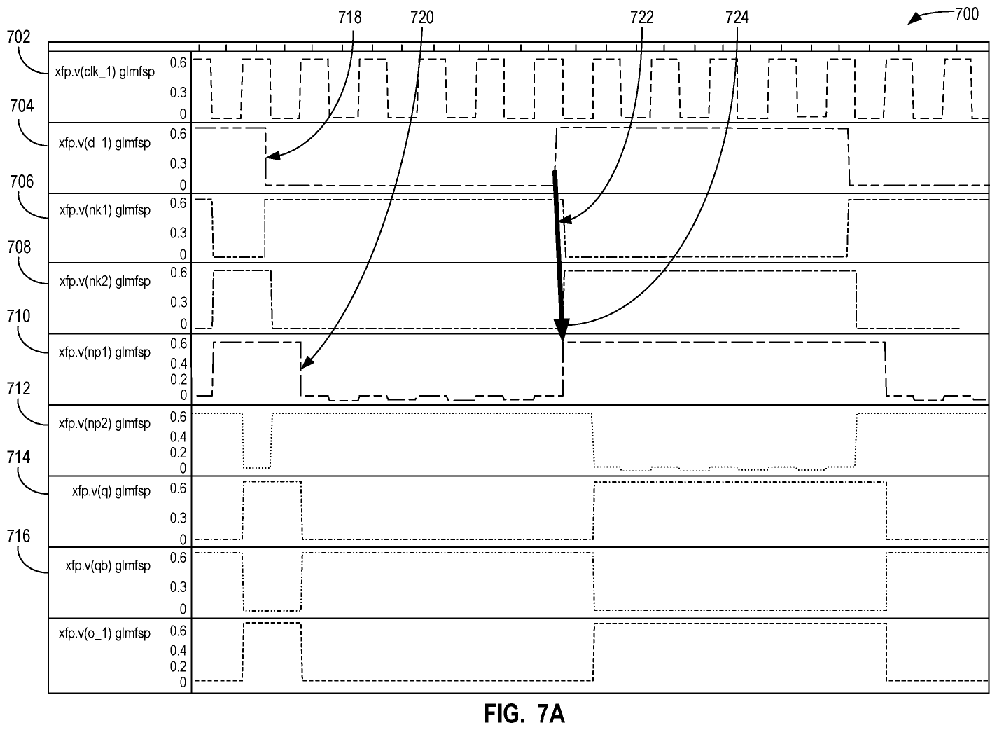

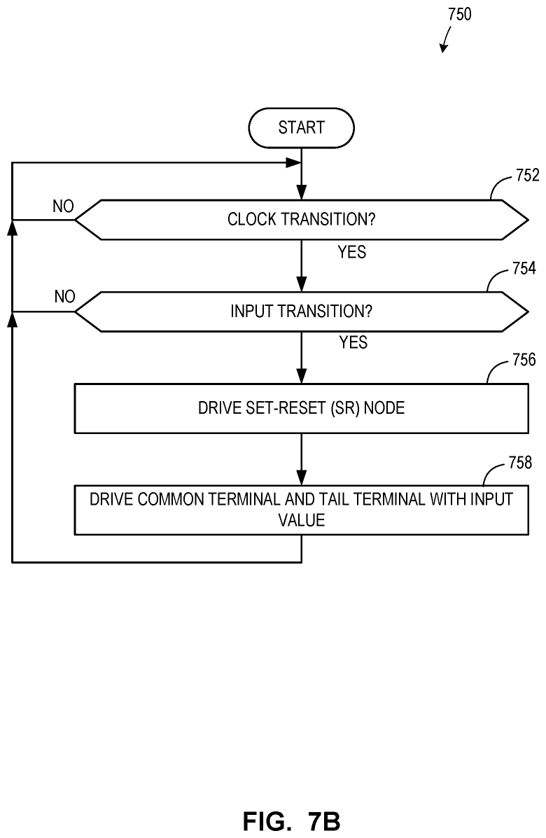

FIG. 7A is a timing diagram 700 to illustrate example operation of the self-gating circuits of FIGS. 3-6. In the illustrated example of FIG. 7A, the timing diagram 700 includes an example clock waveform 702, an example data input waveform 704, an example node NK1 waveform 706, an example node NK2 waveform 708, an example node NP1 waveform 710, an example node NP2 waveform 712, an example output node (Q) waveform 714, and an example inverted output node (Qb) 716. As described above, traditional implementations of flip-flop circuits exhibit switching on internal nodes (e.g., NP1 and NP2) during clock cycles even when a data input (e.g., the example data input waveform 704) is not changing (non-transient). However, such energy-wasting internal switching is blocked, suppressed and/or otherwise prohibited due to the blocking functionality enabled by the example tail circuit 550, the example lower stack 350 (corresponding to node NP2 236), the example lower stack 450 (corresponding to node NP1 238), the example common node 308 (corresponding to node NP2g 310), and the example common node 408 (corresponding to node NP1g 410).

As shown in the illustrated example of FIG. 7A, in response to a change in the data input waveform 704 (see arrow 718), internal node NP1 238 changes state as intended, as shown by the node NP1 waveform 710 (see arrow 720). Unlike traditional flip-flop implementations that continue to switch the internal node during each cycle of the clock, the example self-gating flip-flop 600 of FIG. 6 maintains the state of internal node NP1 unless and until another change in the input waveform 704 is detected. In other words, state changes for the internal node are prohibited when input waveform 704 activity is non-transient, and state changes for the internal node are permitted with input waveform 704 activity is transient. For instance, the illustrated example of FIG. 7A indicates that the input waveform 704 changes (see arrow 722), which causes the internal node NP1 238 to change state (see arrow 724).

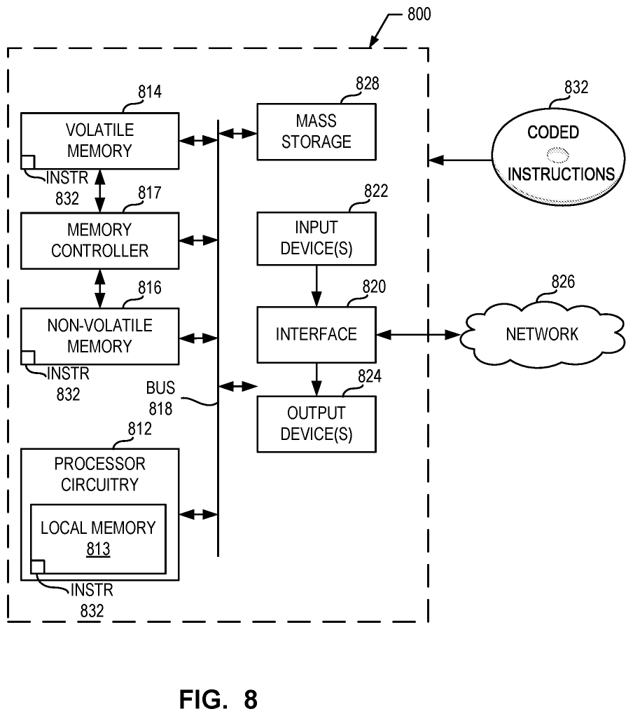

Flowchart(s) representative of example machine readable instructions, which may be executed by programmable circuitry to implement and/or instantiate the flip-flop circuitry 500 of FIGS. 5 and 6 and/or the self-gating circuit 300 of FIG. 3 and/or the self-gating circuit 400 of FIG. 4 and/or representative of example operations which may be performed by programmable circuitry to implement and/or instantiate the aforementioned structure, are shown in FIG. 7B. The machine readable instructions may be one or more executable programs or portion(s) of one or more executable programs for executing by programmable circuitry, such as the processor circuitry 812 of FIG. 8 shown in the example processor platform 800 discussed below in connection with FIG. 8. In some examples, the example instructions of FIG. 7B are performed by one or more of the example self-gating circuit 300 of FIG. 3, the example self-gating circuit 400 of FIG. 4 and/or the example self-gating flip-flop of FIGS. 5 and/or 6.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. 7B, many other methods of implementing the example self-gating circuit 300, 400, 500 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIG. 7B may be implemented using executable instructions (e.g., computer readable and/or machine readable instructions) stored on one or more non-transitory computer readable and/or machine readable media, or may represent the actions of the example self-gating circuit 300 of FIG. 3, the example self-gating circuit 400 of FIG. 4, and/or the example self-gating flip-flop of FIGS. 5 and/or 6. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

FIG. 7B is a flowchart representative of example machine-readable instructions and/or example operations 750 that may be executed, instantiated and/or performed by programmable circuitry and/or by example self-gating circuitry disclosed herein to improve flip-flop toggle efficiency. The example machine-readable instructions and/or the example operations 750 of FIG. 7B begin at block 752, at which the example self-gating circuitry 500, 600 determines and/or otherwise detects a clock transition. If not, control returns to block 752, otherwise the example self-gating circuitry 500, 600 determines if an input transition occurs (block 754). If not, control returns to block 752. On the other hand, in response to an input transition (block 754), the example self-gating circuitry 500, 600 drives a set-reset (SR) node (block 756), such as the example node NP2g 310. The example self-gating circuitry 500, 600 drives a common terminal and a tail terminal with the corresponding input value (block 758), such as the example common node 308 and the example tail circuit 550 of FIG. 3.

In some examples disclosed herein, NMOS devices may be shared between clock nodes, nodes for NP1 and nodes for NP2. Briefly returning to the illustrated example of FIG. 5, NMOS sharing is available for particular pairs of gates that carry complementary signals, which allows a reduction in device count and device width without speed losses. In some examples, NAND-2 may be shared with NAND-3 as they have a common clock input. For instance, transistors of NAND-2 may be shared with transistors of NAND-3 or, stated differently, the same transistors may be used for functional capabilities of NAND-2 and NAND-3. In some examples, NAND-1 may be shared with NAND-5 as they have a common input with node NP2. Additionally, in some examples NAND-4 may be shared with NAND-6 as they have a common input with node NP1.

As described above, “including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the-30-xample-30-nn in different examples or claims does not imply that a combination of features is not feasible and/or advantageous.

FIG. 8 is a block diagram of an example programmable circuitry platform 800 structured to execute and/or instantiate the example machine-readable instructions that may correspond with use-case activities in which flip-flop logic is employed. The programmable circuitry platform 800 can be, for example, a server, a personal computer, a workstation, a self-learning machine (e.g., a neural network), a mobile device (e.g., a cell phone, a smart phone, a tablet such as an iPad™M), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, a system-on-a-chip (SoC), or any other type of computing and/or electronic device.

The programmable circuitry platform 800 of the illustrated example includes programmable circuitry 812. The programmable circuitry 812 of the illustrated example is hardware. For example, the programmable circuitry 812 can be implemented by one or more integrated circuits, logic circuits, FPGAs, microprocessors, CPUs, GPUs, DSPs, and/or microcontrollers from any desired family or manufacturer. The programmable circuitry 812 may be implemented by one or more semiconductor based (e.g., silicon based) devices. In this example, the programmable circuitry 812 implements one or more example self-gating flip-flops and/or latch circuitry disclosed herein.

The programmable circuitry 812 of the illustrated example includes a local memory 813 (e.g., a cache, registers, etc.). The programmable circuitry 812 of the illustrated example is in communication with main memory 814, 816, which includes a volatile memory 814 and a non-volatile memory 816, by a bus 818. The volatile memory 814 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 816 may be implemented by flash memory and/or any other desired type of memory device.

Access to the main memory 814, 816 of the illustrated-31-xamplee is controlled by a memory controller 817. In some examples, the memory controller 817 may be implemented by one or more integrated circuits, logic circuits, microcontrollers from any desired family or manufacturer, or any other type of circuitry to manage the flow of data going to and from the main memory 814, 816.

The programmable circuitry platform 800 of the illustrated example also includes interface circuitry 820. The interface circuitry 820 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 822 are connected to the interface circuitry 820. The input device(s) 822 permit(s) a user (e.g., a human user, a machine user, etc.) to enter data and/or commands into the programmable circuitry 812. The input device(s) 822 can be implemented by, for example, an audio sensor, a microphone, a camera (still or video), a keyboard, a button, a mouse, a touchscreen, a trackpad, a trackball, an isopoint device, and/or a voice recognition system.

One or more output devices 824 are also connected to the interface circuitry 820 of the illustrated example. The output device(s) 824 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 820 of the illustrated example, thus, typically includes a graphics driver card, a graphics driver chip, and/or graphics processor circuitry such as a GPU.

The interface circuitry 820 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 826. The communication can be by, for example, an Ethernet connection, a digital subscriber line (DSL) connection, a telephone line connection, a coaxial cable system, a satellite system, a beyond-line-of-site wireless system, a line-of-site wireless system, a cellular telephone system, an optical connection, etc.

The programmable circuitry platform 800 of the illustrated example also includes one or more mass storage discs or devices 828 to store firmware, software, and/or data. Examples of such mass storage discs or devices 828 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 832, which may be

implemented by the machine readable instructions of FIGS. [Flowcharts], may be stored in the mass storage device 828, in the volatile memory 814, in the non-volatile memory 816, and/or on at least one non-transitory computer readable storage medium such as a CD or DVD which may be removable.

From the foregoing, it will be appreciated that example apparatus, and methods have been disclosed that improve an efficiency metric of flip-flop logic circuitry. In particular, typical flip-flop circuitry exhibits internal terminal switching behaviors in an SR latch circuit(s) that consume energy resources and/or generate heat during circumstances where flip-flop input(s) are non-transient. As such, examples disclosed herein improve energy consumption metrics corresponding to flip-flop logic implementation in any number of target end-uses including, but not limited to, SoC platforms, FPGA circuits, programmable logic circuits, ASICs and/or glue logic. Disclosed systems, apparatus, articles of manufacture, and methods are accordingly directed to one or more improvement(s) in the operation of a machine such as a computer or other electronic and/or mechanical device.

Example methods and apparatus to improve flip-flop toggle efficiency are disclosed herein. Further examples and combinations thereof include the following:

Example 1 includes a circuit comprising an upper flip-flop latch circuit including a first clock input terminal, a first output terminal, and a first data input terminal, a first gating circuit including a first gating transistor, the first gating transistor including a first power input terminal, a first gating output terminal and a gating signal input terminal, the gating signal input terminal coupled to the first input terminal of the first flip-flop latch circuit, a first clock transistor including a clock power input terminal coupled to the first gating output terminal of the first gating transistor, a clock power output terminal, and a clock signal input terminal coupled to the first clock input terminal of the upper flip-flop latch circuit, and a first latch output transistor including a latch power input terminal, a latch power output terminal coupled to the clock power output terminal of the first clock transistor, and a latch input terminal coupled to an output of a second latch output transistor of the upper flip-flop latch circuit.

Example 2 includes the circuit as defined in example 1, wherein the first gating output terminal of the first gating transistor forms a self-gating terminal.

Example 3 includes the circuit as defined in example 2, further including a tail circuit coupled with the self-gating terminal, the tail circuit including a tail input transistor in series with the first gating output terminal of the first gating transistor.

Example 4 includes the circuit as defined in example 3, wherein the tail circuit includes the tail input transistor in series with a tail output transistor and a scan enable transistor.

Example 5 includes the circuit as defined in example 1, further including a lower flip-flop latch circuit including a second clock input terminal, a second output terminal, and a second data input terminal.

Example 6 includes the circuit as defined in example 1, wherein the first gating circuit and a tail circuit share the first gating output terminal.

Example 7 includes the circuit as defined in example 6, wherein the first gating circuit includes P-type metal-oxide semiconductor (PMOS) transistors and the tail circuit includes N-type metal-oxide semiconductor (NMOS) transistors.

Example 8 includes the circuit as defined in example 6, wherein the first gating circuit is coupled to Vcc and the tail circuit is coupled to Vss.

Example 9 includes a flip-flop circuit to reduce terminal switching, comprising a first set-reset (SR) latch circuit including a terminal coupled with an input of a second SR latch circuit, a tail circuit including a series stack of input transistors, an output terminal of the tail circuit forming a self-gating terminal, and a common terminal circuit including a parallel stack of input transistors, an output terminal of the common terminal circuit coupled with the self-gating terminal, the self-gating terminal forming an input to the first SR latch circuit.

Example 10 includes the flip-flop circuit as defined in example 9, wherein the terminal coupled with the input of the second SR latch circuit is an internal terminal.

Example 11 includes the flip-flop circuit as defined in example 9, wherein the series stack of input transistors of the tail circuit includes N-type metal-oxide semiconductor (NMOS) transistors and the parallel stack of input transistors of the common terminal circuit includes P-type metal-oxide semiconductor (PMOS) transistors.

Example 12 includes the flip-flop circuit as defined in example 9, wherein a transient input to the first SR latch circuit is to cause the self-gating terminal to switch state.

Example 13 includes the flip-flop circuit as defined in example 12, wherein at least one of a rising edge or a falling edge of a clock input to the first SR latch circuit causes the self-gating terminal to switch state in response to the transient input.

Example 14 includes the flip-flop circuit as defined in example 9, wherein the first SR latch circuit includes a first NAND gate, and the second SR latch circuit including a second NAND gate, the first NAND gate and the second NAND gate including a common clock input terminal.

Example 15 includes the flip-flop circuit as defined in example 14, wherein transistors of the first NAND gate are shared with transistors of the second NAND gate.

Example 16 includes the flip-flop circuit as defined in example 9, wherein the first SR latch circuit includes a first latch output and the second SR latch circuit includes a second latch output complementary to the first latch output.

Example 17 includes the flip-flop circuit as defined in example 9, wherein the parallel stack of input transistors of the common terminal circuit includes a first gating transistor, a second output transistor and a third scan control transistor.

Example 18 includes the flip-flop circuit as defined in example 9, wherein the series stack of input transistors of the tail circuit includes a data input transistor, an output transistor and a scan control transistor.

Example 19 includes a method to suppress internal node switching, comprising responsive to a first input signal, drive an internal terminal of a set-reset (SR) latch of a flip-flop, drive a common terminal and a tail terminal with the first input signal to form a self-gate terminal as an input to the SR latch, and prohibit a state change of the internal terminal during clock cycle iterations while the first input signal is unchanged.

Example 20 includes the method as defined in example 19, further including permitting the state change of the internal terminal when the first input signal changes.

Example 21 includes the circuit as defined in any one of examples 1 through 5, wherein the upper flip-flop latch circuit is a first flip-flop latch circuit and the lower flip-flop latch circuit is a second flip-flop latch circuit, an output of the first flip-flop circuit coupled with an input to the second flip-flop circuit, and an output of the second flip-flop circuit coupled with an input to the first flip-flop circuit.

Example 22 includes the circuit as defined in any one of examples 1 through 8, wherein the circuit includes a system-on-a-chip (SoC).

Example 23 includes the circuit as defined in example 1, further including memory coupled with the circuit to store data.

Example 23 includes the circuit as defined in example 1, further including a processor coupled to the circuit, the processor further coupled to memory and a display.

Example 24 includes means to perform a method as set forth in any preceding example.

Example 25 is a machine-readable storage including machine-readable instructions that, when executed, cause processor circuitry to implement a method as set forth in any preceding example.

Example 26 is a computer program including instructions that, when the program is executed by a computer, cause the computer to carry out a method as set forth in any preceding example.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A circuit comprising:
a first flip-flop latch circuit including a first clock input terminal, a first output terminal, and a first data input terminal;
a first gating circuit including a first gating transistor, the first gating transistor including a first power input terminal, a first gating output terminal and a gating signal input terminal, the gating signal input terminal coupled to the first input terminal of the first flip-flop latch circuit;
a first clock transistor including a clock power input terminal coupled to the first gating output terminal of the first gating transistor, a clock power output terminal, and a clock signal input terminal coupled to the first clock input terminal of the first flip-flop latch circuit; and
a first latch output transistor including a latch power input terminal, a latch power output terminal coupled to the clock power output terminal of the first clock transistor, and a latch input terminal coupled to an output of a second latch output transistor of the first flip-flop latch circuit.

2. The circuit as defined in claim 1, wherein the first gating output terminal of the first gating transistor forms a self-gating terminal.

3. The circuit as defined in claim 2, further including a tail circuit coupled with the self-gating terminal, the tail circuit including a tail input transistor in series with the first gating output terminal of the first gating transistor.

4. The circuit as defined in claim 3, wherein the tail circuit includes the tail input transistor in series with a tail output transistor and a scan enable transistor.

5. The circuit as defined in claim 1, further including a lower flip-flop latch circuit including a second clock input terminal, a second output terminal, and a second data input terminal.

6. The circuit as defined in claim 1, wherein the first gating circuit and a tail circuit share the first gating output terminal.

7. The circuit as defined in claim 6, wherein the first gating circuit includes P-type metal-oxide semiconductor (PMOS) transistors and the tail circuit includes N-type metal-oxide semiconductor (NMOS) transistors.

8. The circuit as defined in claim 6, wherein the first gating circuit is coupled to Vcc and the tail circuit is coupled to Vss.

9. A flip-flop circuit to reduce terminal switching, comprising:
a first set-reset (SR) latch circuit including a terminal coupled with an input of a second SR latch circuit;
a tail circuit including a series stack of input transistors, an output terminal of the tail circuit forming a self-gating terminal; and
a common terminal circuit including a parallel stack of input transistors, an output terminal of the common terminal circuit coupled with the self-gating terminal, the self-gating terminal forming an input to the first SR latch circuit.

10. The flip-flop circuit as defined in claim 9, wherein the terminal coupled with the input of the second SR latch circuit is an internal terminal.

11. The flip-flop circuit as defined in claim 9, wherein the series stack of input transistors of the tail circuit includes N-type metal-oxide semiconductor (NMOS) transistors and the parallel stack of input transistors of the common terminal circuit includes P-type metal-oxide semiconductor (PMOS) transistors.

12. The flip-flop circuit as defined in claim 9, wherein a transient input to the first SR latch circuit is to cause the self-gating terminal to switch state.

13. The flip-flop circuit as defined in claim 12, wherein at least one of a rising edge or a falling edge of a clock input to the first SR latch circuit causes the self-gating terminal to switch state in response to the transient input.

14. The flip-flop circuit as defined in claim 9, wherein the first SR latch circuit includes a first NAND gate, and the second SR latch circuit including a second NAND gate, the first NAND gate and the second NAND gate including a common clock input terminal.

15. The flip-flop circuit as defined in claim 14, wherein transistors of the first NAND gate are shared with transistors of the second NAND gate.

16. The flip-flop circuit as defined in claim 9, wherein the first SR latch circuit includes a first latch output and the second SR latch circuit includes a second latch output complementary to the first latch output.

17. The flip-flop circuit as defined in claim 9, wherein the parallel stack of input transistors of the common terminal circuit includes a first gating transistor, a second output transistor and a third scan control transistor.

18. The flip-flop circuit as defined in claim 9, wherein the series stack of input transistors of the tail circuit includes a data input transistor, an output transistor and a scan control transistor.

19. A method to suppress internal node switching, comprising:
responsive to a first input signal, drive an internal terminal of a set-reset (SR) latch of a flip-flop;
drive a common terminal and a tail terminal with the first input signal to form a self-gate terminal as an input to the SR latch; and
prohibit a state change of the internal terminal during clock cycle iterations while the first input signal is unchanged.

20. The method as defined in claim 19, further including permitting the state change of the internal terminal when the first input signal changes.
